(19) United States
(12) Patent Application Publication
(10) Pub. No.: US 2008/0254217 A1
(43) Pub. Date: Oct. 16, 2008

(54) FINE CONTROL OF VAPORIZED ORGANIC MATERIAL

(76) Inventor: Michael L. Boroson, Rochester, NY (US)

Correspondence Address: Frank Pincelli;Patent Legal Staff, Eastman Kodak Company, 343 State Street, Rochester, NY, 14650-2201, US

(21) Appl. No.: 11/735,544

(22) Filed: Apr. 16, 2007

(51) Int. Cl. C23C 16/00

(52) U.S. Cl. 427/248.1

(57) ABSTRACT

A method for vaporizing organic components and delivering the vapor through opening(s) in a manifold to a substrate surface spaced from the manifold to form a film composed of at least two organic components, comprising: delivering a first quantity of a single first organic component into a vaporization device where the component is vaporized and delivered at a first predetermined rate to the manifold; delivering into a transport apparatus a quantity of a mixture of organic components in a predetermined ratio that includes the first organic component; the transport apparatus delivering the mixture of organic components at a second predetermined rate to a flash heating region wherein the mixture is vaporized and delivered to the manifold; and mixing the organic components in the manifold, which permits the mixed vaporized components to be deposited through the opening(s) onto the substrate surface to form the film.

### FIELD OF THE INVENTION

The present invention relates to the field of physical vapor deposition where source materials are heated to a temperature to cause vaporization and create a vapor plume to fort a thin film on a surface of a substrate.

### BACKGROUND OF THE INVENTION

An OLED device includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing and capability for full-color flat emission displays. Tang et al. have described this multilayer OLED device in U.S. Pat. Nos. 4,769,292 and 4,885,211.

Physical vapor deposition in a vacuum environment is the principal means of depositing thin organic material films as used in small molecule OLED devices. Such methods are well known, for example Barr in U.S. Pat. No. 2,447,789 and Tanabe et al. in EP 0 982 411. The organic materials used in the manufacture of OLED devices are often subject to degradation when maintained at or near the desired rate dependant vaporization temperature for extended periods of time. Exposure of sensitive organic materials to higher temperatures can cause changes in the structure of the molecules and associated changes in material properties.

To overcome the thermal sensitivity of these materials, only small quantities of organic materials have been loaded in sources and they are heated as little as possible. In this manner the material is consumed before it has reached the temperature exposure threshold to cause significant degradation. The limitations with this practice are that the available vaporization rate is very low due to the limitation on heater temperature, and the operation time of the source is very short due to the small quantity of material present in the source. It has been necessary to vent the deposition chamber, disassemble and clean the vapor source, refill the source, reestablish vacuum in the deposition chamber and degas the just-introduced organic material over several hours before resuming operation. The low deposition rate and the frequent and time consuming process associated with recharging a source has placed substantial limitations on the throughput of OLED manufacturing facilities.

A secondary consequence of heating the entire organic material charge to roughly the same temperature is that it is impractical to mix additional organic materials, such as dopants, with a host material unless the vaporization behavior and vapor pressure of the dopant is very close to that of the host material. This is generally not the case and as a result, such devices frequently require the use of separate sources to co-deposit host and dopant materials.

A consequence of using single component sources is that many sources are required in order to produce films containing a host and multiple dopants. These sources are arrayed one next to the other with the outer sources angled toward the center to approximate a co-deposition condition. In practice, the number of linear sources used to co-deposit different materials has been limited to three. This restriction has imposed a substantial limitation on the architecture of OLED devices, increases the necessary size and cost of the vacuum deposition chamber and decreases the reliability of the system. Additionally, the use of separate sources creates a gradient effect in the deposited film where the material in the source closest to the advancing substrate is overrepresented in the initial film immediately adjacent the substrate while the material in the last source is overrepresented in the final film surface.

A further limitation of such sources is that the geometry of the vapor manifold changes as the organic material charge is consumed. This change requires that the heater temperature change to maintain a constant vaporization rate. It is observed that the overall plume shape of the vapor exiting the orifices can change as a function of the organic material thickness and distribution in the source, particularly when the conductance to vapor flow in the source with a full charge of material is low enough to sustain pressure gradients from non-uniform vaporization within the source. In this case, as the material charge is consumed, the conductance increases and the pressure distribution and hence overall plume shape improve.

US Publication No. 2006/0062919 of Long et al., describes an apparatus that allows vaporization of organic materials at a predetermined rate over long periods of time without concomitant material degradation. However, it is difficult to use such an apparatus to make minor adjustment in vapor composition, for example, if the materials are off aim. To change the composition of the deposited material when using a single feeding apparatus with a mixture of materials would require emptying and refilling the apparatus. If using separate feeding apparatus for each component, it is difficult to accurately feed materials at vastly different rates. For example, to produce a deposited material that has 1% of a dopant in a host material would require a 99:1 ratio of feeding rates, which would be difficult to control accurately. Therefore, such apparatus can be difficult to use in manufacturing processes.

### SUMMARY OF THE INVENTION

It is therefore an object of the present invention to provide a method for vaporizing organic components to form a film on a substrate.

This object is achieved by a method for vaporizing organic components and delivering the vapor through opening(s) in a manifold to a substrate surface spaced from the manifold to form a film composed of the organic components, comprising:

a. delivering a first quantity of a single first organic component into a vaporization device where the component is vaporized and delivered at a first predetermined rate to the manifold:

b. delivering into a transport apparatus a quantity of a mixture of organic components in a predetermined ratio that includes the first organic component;

c. the transport apparatus delivering the mixture of organic components at a second predetermined rate to a flash heating region wherein the mixture is vaporized and delivered to the manifold; and

d. mixing the organic materials in the manifold, which permits the mixed vaporized components to be deposited through the opening(s) onto the substrate surface to form the film.

### Advantages

It is an advantage of this invention that it provides a method of forming a film by vaporizing organic components wherein the composition of the film can easily be adjusted without stopping, emptying, and refilling the apparatus. It is a further advantage of this invention that the composition can be varied over a wide range without requiring large differences in the feed rates of the material in multiple transport apparatus. It is a further advantage of this invention that it can be applied to compositions of any number of components.

### BRIEF DESCRIPTION OF THE DRAWINGS

FIG. 1 is a three-dimensional view of one embodiment of an apparatus that can be used according to the present invention for vaporizing organic components and delivering the vapor to a substrate surface to form a film composed of the organic components;

FIG. 2 is a cross-sectional view of one embodiment of a portion of the above apparatus;

FIG. 3 shows a cross-sectional view of another apparatus that can be used according to the present invention for vaporizing organic components and delivering the vapor to a substrate surface to form a film composed of at least two organic components;

FIG. 4 shows a schematic of another apparatus that can be used according to the present invention for vaporizing organic components and delivering the vapor to a substrate surface to form a film composed of at least two organic components;

FIG. 5 shows a schematic of another apparatus that can be used according to the present invention for vaporizing organic components and delivering the vapor to a substrate surface to form a film composed of at least two organic components;

FIG. 6 is a block diagram showing one embodiment of the method of this invention;

FIG. 7 is a block diagram showing another embodiment of the method of this invention,

FIG. 8 is a block diagram showing another embodiment of the method of this invention;

FIG. 9 shows a three-component diagram of a range of compositions wherein three vaporization devices can be used; and

FIG. 10 is a cross-sectional view of an OLED device structure that can be prepared with the present invention.

### DETAILED DESCRIPTION OF THE INVENTION

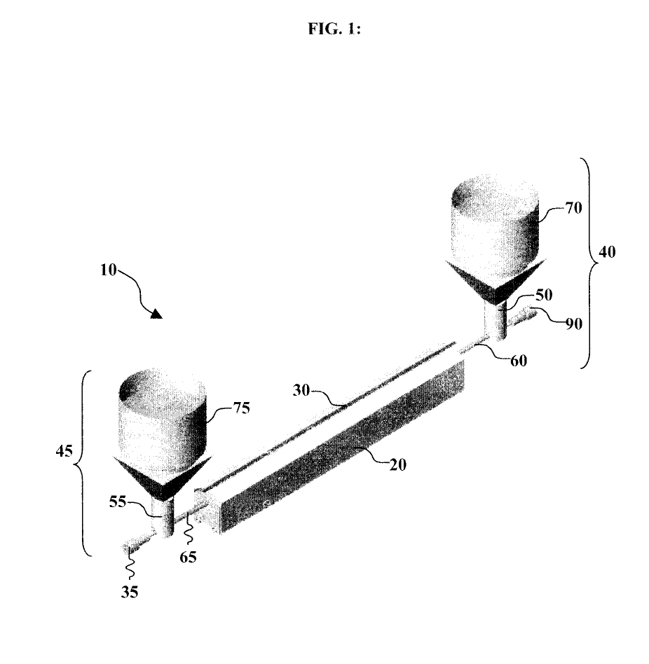

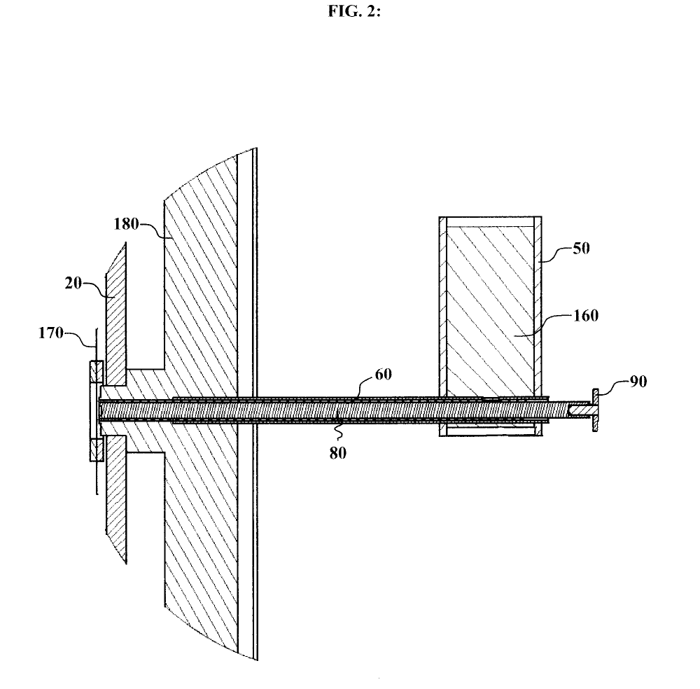

Turning now to FIG. 1, there is shown a three-dimensional view of one embodiment of an apparatus that can be used according to the present invention for vaporizing organic components and delivering the vapor to a substrate surface to form a film composed of at least two organic components. In US Publication No. 2006/0062919, by Long et al., the contents of which are incorporated herein by reference, have described vaporization apparatus 10. Vaporization apparatus 10 includes manifold 20, attached first transport apparatus 40, and attached second transport apparatus 45. Transport apparatus 40 includes at least first container 50 and transport path 60. Transport apparatus 45 includes at least second container 55 spaced from first container 50 and transport path 65. A first quantity of a first organic material 160 as shown in FIG. 2, is delivered into first container 50 of transport apparatus 40. A second quantity of a second organic material is delivered into second container 55 of second transport apparatus 45. In one embodiment of this invention, the first organic material 160 is a single first organic component, and the second organic material is a mixture of organic components in a predetermined ratio that includes the first organic component. For the purposes of this discussion, a single organic material is an organic material that consists of substantially one component. Thus, an organic component that contains minor impurities that are not meant to be present, but are present due to the manufacturing process, will be considered a single organic component. One useful example of this embodiment is wherein the first organic component is a host material and the mixture of organic materials is a mixture of the host material and a dopant.

In another embodiment of this invention, the first organic material 160 is a first mixture of two or more organic components having a first predetermined ratio of the components, and the second organic material is a second mixture of two or more organic components that includes at least one organic component of the first mixture. The second mixture in this embodiment has a second predetermined ratio of organic components that is different from the first predetermined ratio. One example of this embodiment is where the first mixture is a mixture of a host and a dopant in a first predetermined ratio, and the second mixture is a mixture of the host and the dopant in a second, different predetermined ratio. Another example is wherein the first mixture is a mixture of a host and a dopant, and the second mixture is a mixture of the host and a co-host. Another example is wherein the first mixture is a mixture of a host and a co-host, and the second mixture is a mixture of the host the co-host, and a dopant.

Transport apparatus 40 can also include third container 70, and transport apparatus 45, including motor 35 can include fourth container 75. Third container 70 and fourth container 75 can function as reservoirs for first container 50 and second container 55, respectively, as described by Long et al. Manifold 20 includes one or more openings 30 through which vaporized organic components can be delivered onto a substrate surface. Manifold 20 is shown in an orientation whereby it can form a layer on a horizontally oriented substrate, but it is not limited to this orientation. Manifold 20 can be oriented vertically and can form a layer on a vertical substrate. Transport apparatus 40 and transport apparatus 45 are shown attached to opposite sides of manifold 20, but they can also be attached to the same side of manifold 20, or to the bottom of manifold 20 if the manifold is in a vertical orientation. Manifold 20 can be an area manifold with a two-dimensional array of apertures, a linear manifold with a one-dimensional array of apertures, or a point manifold with a single aperture.

Turning now to FIG. 2, there is shown in further detail, a cross-sectional view of one embodiment of a portion of the above apparatus for transporting and vaporizing organic components. Transport apparatus 40 includes an auger 80 driven by a motor 90, which delivers the first organic material 160 along transport path 60 into manifold 20 and heating element 170 at a predetermined rate. Heating element 170 can be for example, a heated screen and has been previously described in detail by Long et al. Transport apparatus 40 includes a flash heating region, which in this embodiment, is the region of transport path 60 immediately adjacent to heating element 170. A thin cross-section of the organic material is rapidly heated to the temperature of heating element 170, by virtue of contact and thennal conduction, whereby the thin cross-section of first organic material powder is vaporized and delivered to manifold 20. The temperature of the flash heating region is selected as described in US Publication No. 2006/0062919, such that the organic material vaporizes rapidly and does not accumulate in the flash heating region. Auger 80 continuously meters the organic material to the flash heating region when vaporization of the organic material is desired, and can be turned off to stop vaporization when vaporization of the organic material is not desired. Similarly, second transport apparatus 45 of FIG. 1 delivers the corresponding second organic material to a corresponding second flash heating region at a second predetermined rate. The second organic material is vaporized in the second flash heating region and delivered to manifold 20. The first and second vaporized organic materials are mixed in manifold 20, and subsequently delivered to a substrate surface to form a film. The structure of transport apparatus 40 and the rotation rate of auger 80 control the rate at which organic material is delivered to heating element 170. This linearly controls the rate of vaporization and therefore the rate at which organic material leaves the manifold in the vapor state. Thus a predetermined rate of delivering the organic material to the auger 80 and to the flash heating region controls the deposition rate of the vaporized organic material onto the desired surface to form a film. With two such structures, as in FIG. 1, the relative predetermined rates of delivering the first and second organic materials to the respective augers and the respective flash heating regions controls the relative partial pressures of the first and second organic materials in the manifold, and hence their relative deposition rates and concentrations in the deposited film. The predetennined rates of delivering the first organic material 160 or the second organic material, or both, to their corresponding flash heating regions by the first or second transport apparatus can be changed to change the composition of the film.

By choosing the composition of the organic material, and by selecting the predetermined rates of delivery of the organic materials, it is possible to have fine control over the composition of the resulting film. If, for example, films are desired comprising 14-16% of a dopant in a host. one can use a first mixture of 10% dopant in the host, and a second mixture of 20% dopant in the host. One can then provide the two mixtures in a ratio of rates from 3:2 for a film of 14% dopant in host, to 2:3 for a film of 16% dopant in host. It is desirable to limit the ratio of the higher to the lower predetermined rates to less than 20:1 to provide good control. The embodiments herein comprise three or more individually vaporized organic materials. It is desirable that the ratio of the highest to the lowest of all predetermined rates be less than 20:1 on a weight or a volume basis. These conditions can be achieved by selecting the ratios of components in the mixtures of organic components.

Additionally, base 180 can be included to allow at least a portion of transport apparatus 40 to be temperature controlled. Base 180 is a heat-dissipating structure to prevent much of the heat produced by heating element 170 fiom traversing the length of transport path 60, and thus keeps the bulk of the organic material significantly cooler than the conditions it experiences in the flash heating region immediately adjacent to heating element 170. Heat dissipation by base 180 can include active cooling by well-known means, for example, by passing a cooling fluid through tubes or channels (not shown) in base 180. Means of heat dissipation for base 180 have been described in U.S. Publication No. 2005/0186340 and in U.S. Publication No. 2006/0099345. A steep thermal gradient thereby created protects all but the immediately vaporizing material from the high temperatures.

When an organic material is a mixture of two or more different organic components, each one can have a different vaporization temperature. The temperature of heating element 170 is chosen such that the vaporization is delivery-rate limited, that is, the vapor pressure at the heating element temperature is substantially above the desired partial pressure of that component in the manifold, so that each of the organic components simultaneously vaporizes. The vaporization temperature can be determined by various means, as described in US Publication No. 2006/0062919.

It is further possible to provide more than two transport apparatus for delivering more than two mixtures of organic components to corresponding flash heating regions, and thus to the manifold and to the surface of the substrate.

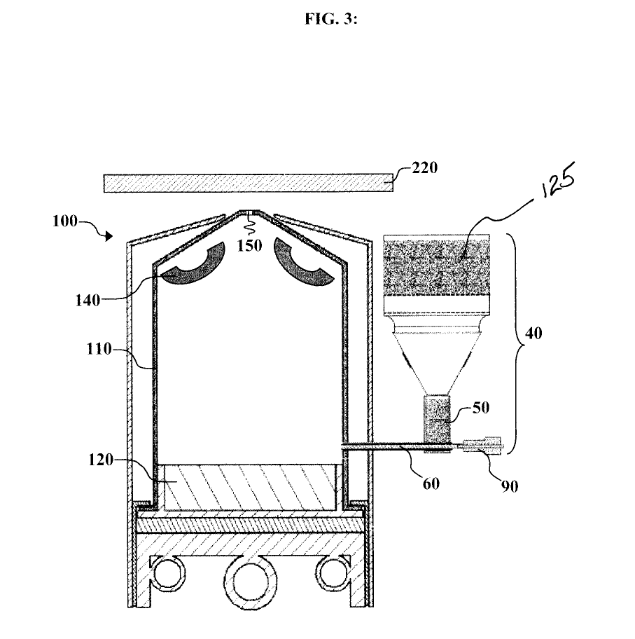

Turning now to FIG. 3, there is shown a cross-sectional view of another apparatus that can be used according to the present invention for vaporizing organic components and delivering the vapor to a substrate surface to form a film composed of at least two organic components. This apparatus can be used in the embodiment of this invention wherein a first organic material 120 is a single first organic component and a second organic material is a mixture of organic components that includes the first organic component. Vaporization apparatus 100 is a vaporization source that includes manifold 110 for containing vaporized organic components. Manifold 110 includes one or more openings 150 through which the vaporized organic material can be delivered for deposition onto the surface of substrate 220 spaced from manifold 110. A quantity of single first organic component 120 is delivered to vaporization apparatus 100. Vaporization apparatus 100 further includes a vaporization device, for example, one or more heating elements 140, for example radiant heaters, to heat first organic component 120 above its vaporization temperature and deliver it to manifold 110 at a first predetennined rate. Vaporization apparatus 100 further includes a transport apparatus 40, for example with an auger, as shown in other apparatus embodiments. A quantity of a mixture of organic components 125 in a predetermined ratio is delivered to transport apparatus 40, which then delivers the mixture of organic components at a second predetermined rate to a flash heating region, for example, a penreable heating element as shown in other apparatus embodiments. Mixture of organic components 125 includes first organic component 120. Mixture of organic components 125 is thus vaporized and delivered to manifold 110 at a predetermined rate. The vaporized organic components are mixed in manifold 110, which permit the mixed vaporized components to be deposited, through openings 150 of manifold 110, onto the surface of substrate 220 to form a film. Changing the predetermined rates of vaporization of first organic component 120, or that of mixture of organic components 125, or both can change the composition of the film.

Other embodiments of this apparatus are possible. For example, first organic component 120 can be heated in a vaporization device such as a crucible or vaporization boat inside manifold 110 as well-known in the art. Vaporization apparatus 100 can include two or more vaporization devices such that at least two single organic components are vaporized and delivered at predetermined rates to manifold 110. Vaporization apparatus 100 can include more than one transport apparatus 40 for delivering more than one mixture of organic components at predetermined rates to corresponding flash heating regions no and thus to manifold 110.

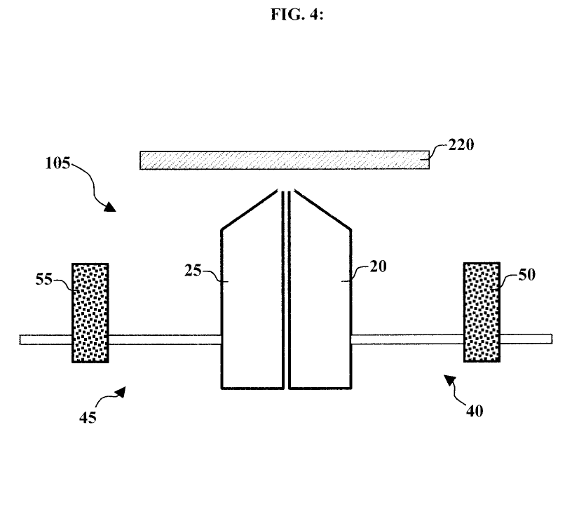

Turning now to FIG. 4, there is shown a schematic view of another apparatus that can be used according to the present invention for vaporizing organic components and delivering the vapor to a substrate surface to form a film composed of at least two organic components. Vaporization apparatus 105 serves the same function, and can be used in the same embodiments, as vaporization apparatus 10 in FIG. 1. However, vaporization apparatus 105 includes two manifolds, a first manifold 20 and a second manifold 25. The first organic material 160 as described above, (for example, a single organic component or a mixture of organic components) is delivered by first transport apparatus 40 into first manifold 20. The second organic material as described above, (for example, a mixture of organic components including at least one component from the first organic material 160 in a different concentration ratio) is delivered by second transport apparatus 45 into second manifold 25. There is a corresponding flash heating region for each manifold as described above wherein the organic materials are vaporized into their corresponding manifolds. The vaporized components are delivered through openings in the manifolds to the space between first and second manifolds 20 and 25 and substrate 220, wherein the components are mixed, permitting the mixed organic components to be deposited onto the surface of substrate 220 to form a film.

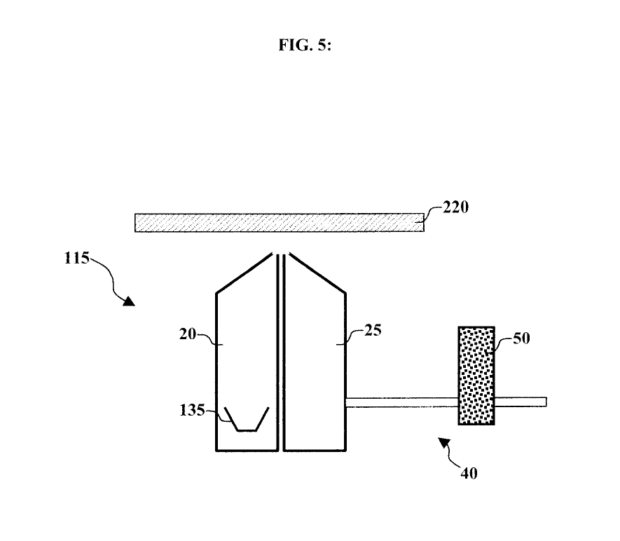

Turning now to FIG. 5, there is shown a schematic view of another apparatus that can be used according to the present invention for vaporizing organic components and delivering the vapor to a substrate surface to form a film composed of at least two organic components. Vaporization apparatus 115 serves the same function, and can be used in the same embodiments, as vaporization apparatus 100 in FIG. 3. However, vaporization apparatus 115 includes two manifolds, a first manifold 20 and a second manifold 25. The first organic component as described above is delivered into first manifold 20, for example, into a vaporization device such as crucible 135, where it can be heated and vaporized at a predetermined rate into first manifold 20, and thus through openings to the space between first manifold 20 and substrate 220. Transport apparatus 40 into second manifold 25 as described above delivers the mixture of organic components. There is a flash heating region for second manifold 25 as described above wherein the mixture of organic components is vaporized into second manifold 25. The vaporized components are delivered through openings in second manifold 25 to the space between the manifold and substrate 220. The vaporized components from both manifolds are mixed in the space between first and second manifolds 20 and 25 and substrate 220, permitting the mixed organic components to be deposited onto the surface of substrate 220 to form a film.

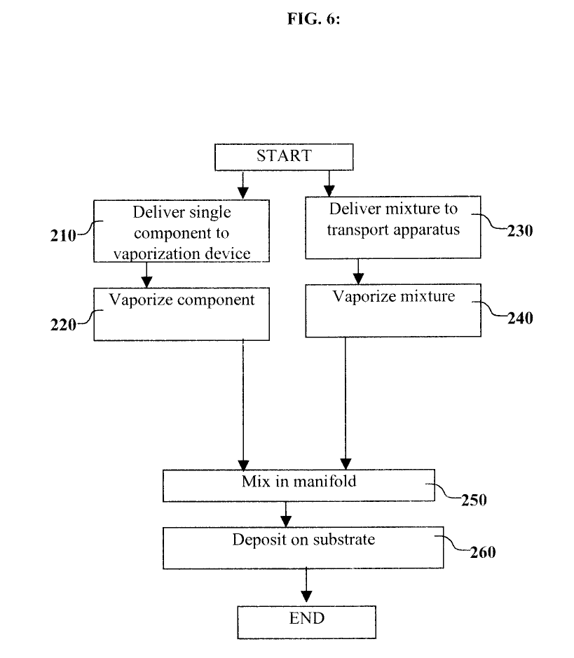

Turning now to FIG. 6, there is shown a block diagram showing one embodiment of the method of this invention for vaporizing organic components and delivering the vapor to a substrate surface to form a film. Initially, a single organic component is delivered to a vaporization device (Step 210), where it is vaporized into the manifold (Step 220). This can be accomplished by placing a charge of the component into the manifold and heating it (as in FIG. 3), or by delivering the component by a transport apparatus (as in FIG. 1). A mixture of organic components is delivered to a transport apparatus, as shown in FIG. 1 or FIG. 3 (Step 230). The transport apparatus delivers the mixture to a flash heating region, where it is vaporized anrd delivered into the manifold (Step 240). The components vaporized in Steps 220 and 240 mix in the manifold (Step 250), and are delivered through openings in the manifold to a substrate, where the mixed components are deposited to form a film (Step 260).

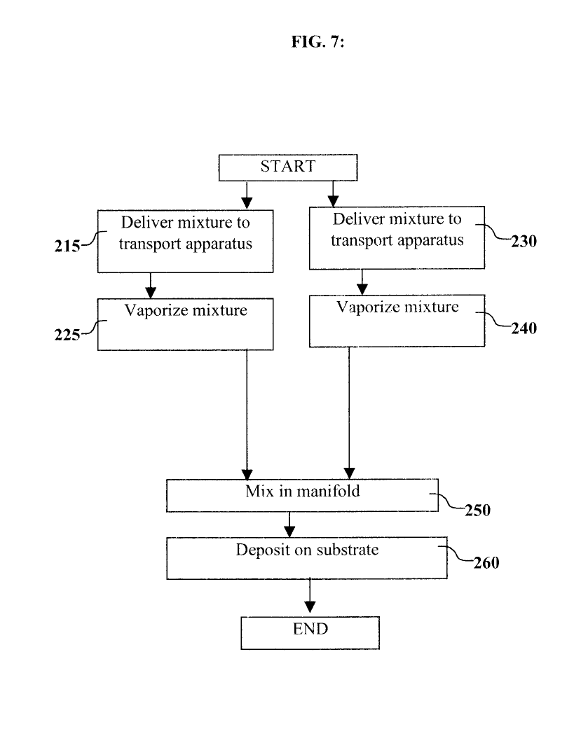

Turning now to FIG. 7, and referring to FIG. 1, there is shown a block diagram showing another embodiment of the method of this invention. A first mixture of organic components is delivered to a transport apparatus (Step 215). The first transport apparatus delivers the mixture to a first flash heating region, where it is vaporized and delivered into the manifold (Step 225). A second mixture of organic components is delivered to a second transport apparatus (Step 230). The second transport apparatus delivers the mixture to a second flash heating region, where it is vaporized and delivered into the manifold (Step 240). The components vaporized in Steps 225 and 240 mix in the manifold (Step 250), and are delivered through openings in the manifold to a substrate, where the mixed components are deposited to form a film (Step 260).

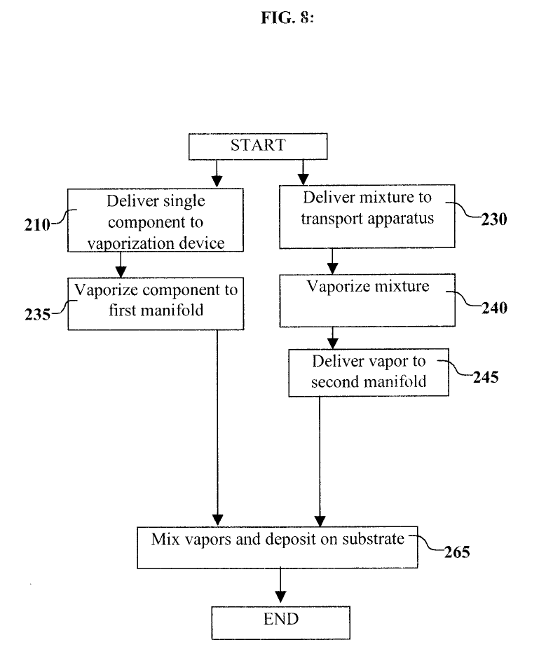

Turning now to FIG. 8, and referring to FIG. 5, there is shown a block diagram showing another embodiment of the method of this invention. Initially, a single organic component is delivered to a first manifold of a vaporization device (Step 210), where it is vaporized into the manifold (Step 235). A mixture of organic components is delivered to a transport apparatus (Step 230). The transport apparatus delivers the mixture to a flash heating region (Step 240), where it is vaporized and delivered into the second manifold (Step 245). The vaporized components in the manifolds are delivered through openings in their respective manifolds to the space between the manifolds and a substrate, where the components are mixed and deposited to form a film (Step 265).

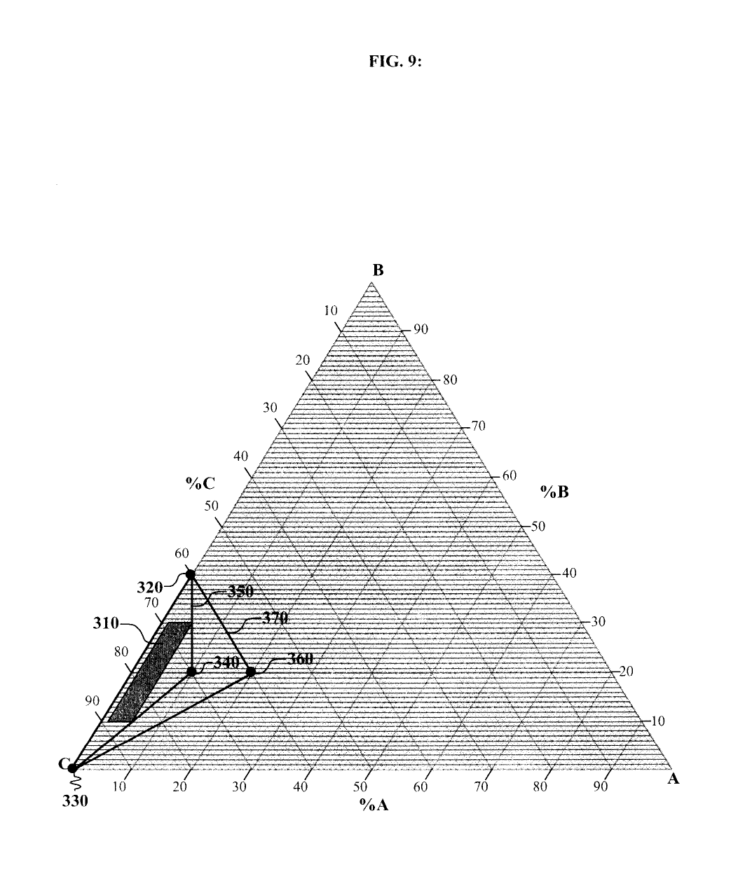

For films comprising more than two components, it can be necessary to have more than two vaporization devices or transport apparatus. In general, to control the concentration of all the components in a deposited film, the total number of vaporization devices and transport apparatus must be at least equal to the total number of components in the film. Turning now to FIG. 9, there is shown a three-component diagram of a range of compositions wherein three vaporization devices can be used. The three components shown are A, B, and C, which can represent for example, dopant, co-host, and host. Desired composition space 310 represents an example range of desired mixtures wherein A is from 1 to 5%, B is from 10 to 30%, and C is the remainder, that is, from 65 to 89% of the mixture. The use of three mixtures, for example, first mixture 320 comprising 40% B and 60% C, second mixture 330 comprising 100% C, and third mixture 340 comprising 10% A, 20% B, and 70% C, enclose the triangle shown as composition gamut 350, which includes all of desired composition space 310. The first, second, and third mixtures can be combined in different ratios to form any desired composition within composition gamut 350. However, it is desirable to not have very disparate ratios of the mixtures. The ratio of any two components should not be greater than 20:1, as that would require metering one of the materials at a very low rate, leading to inconsistencies and inaccuracies. To produce a composition of 4.5% A, 30% B, and 65.5% C with the mixtures of FIG. 9 would require a ratio of first:second:third mixtures of 21:1:18. The first:second mixture ratio is greater than the desired 20:1 ratio. A more favorable result for all compositions within desired composition space 310 would be obtained if the third mixture comprised 20% A, 20% B, and 60% C, as with third mixture 360, which provides a larger composition gamut 370.

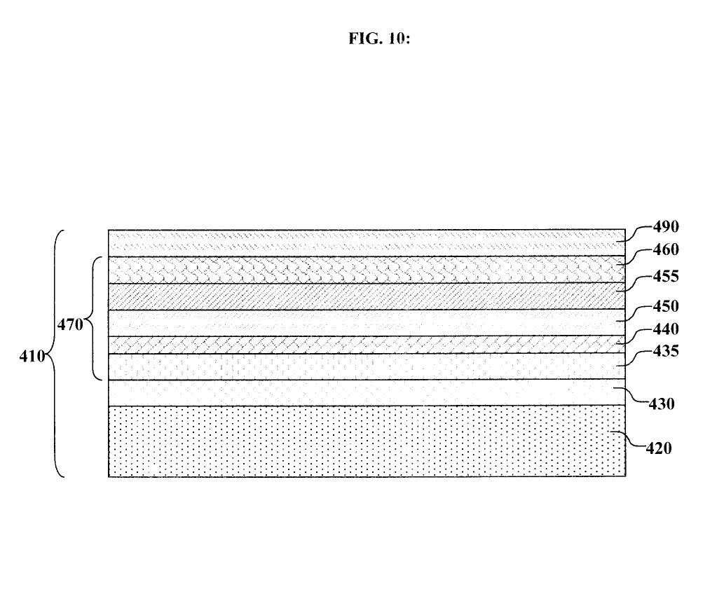

Turning now to FIG. 10, there is shown a cross-sectional view of a pixel of a light-emitting OLED device 410 that can be prepared in part according to the present invention. The OLED device 410 includes at a minimum a substrate 420, a cathode 490, an anode 430 spaced from cathode 490, and a light-emitting laver 450. The OLED device can also include a hole-injecting layer 435, a hole-transporting layer 440, an electron-transporting layer 455, and an electron-injecting layer 460. Hole-injecting layer 435, hole-transporting layer 440, light-emitting layer 450, electron-transporting layer 455, and electron-injecting layer 460 comprise a series of organic layers 470 disposed between anode 430 and cathode 490. Organic layers 470 are the organic component films most desirably formed by the method of this invention. These components will be described in more detail.

Substrate 420 can be an organic solid, an inorganic solid, or a combination of organic and inorganic solids, Substrate 420 can be rigid or flexible and can be processed as separate individual pieces, such as sheets or wafers, or as a continuous roll. Typical substrate materials include glass, plastic, metal, ceramic, semiconductor, metal oxide, semiconductor oxide, semiconductor nitride, or combinations thereof. Substrate 420 can be a homogeneous mixture of materials, a composite of materials, or multiple layers of materials. Substrate 420 can be an OLED substrate, that is a substrate commonly used for preparing OLED devices, for example, active-matrix low-temperature polysilicon or amorphous-silicon TFT substrate. The substrate 420 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials, or any others commonly used in the formation of OLED devices, which can be either passive-matrix devices or active-matrix devices.

An electrode is formed over substrate 420 and is most commonly configured as an anode 430. When EL emission is viewed through the substrate 420, anode 430 should be transparent or substantially transparent to the emission of interest. Common transparent anode materials useful in this invention are indium-tin oxide and tin oxide. but other metal oxides can work including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material. For applications where EL emission is viewed through the top electrode, the transmissive characteristics of the anode material are immaterial and any conductive material can be used, transparent, opaque or reflective. Example conductors for this application include, but are not limited to, gold, iridium, molybdenum, palladium, and platinum. The preferred anode materials, transmissive or otherwise, have a work function of 4.1 eV or greater. Desired anode materials can be deposited by any suitable means such as evaporation, sputtering, chemical vapor deposition, or electrochemical means. Anode materials can be patterned using well-known photolithographic processes.

While not always necessary, it is often useful that a hole-injecting layer 435 be formed over anode 430 in an organic light-emitting display. The hole-injecting material can serve to improve the film formation property of subsequent organic layers and to facilitate injection of holes into the hole-transporting layer. Suitable materials for use in hole-injecting layer 435 include, but are not limited to, porphyrinic compounds as described in U.S. Pat. No. 4,720,432, plasma-deposited fluorocarbon polymers as described in U.S. Pat. No. 6,208,075, and inorganic oxides including vanadium oxide (VOx), molydenum oxide (MoOx), nickel oxide (NiOx), Alternative hole-injecting materials reportedly useful in organic EL devices are described in EP 0 891 121 A1 and EP 1 029 909 A1.

While not always necessary, it is often useful that a hole-transporting layer 440 be formed and disposed over anode 430. Desired hole-transporting materials can be deposited by any suitable means such as evaporation, sputtering, chemical vapor deposition. electrochemical means, thermal transfer, or laser thermal transfer from a donor material, and can be deposited by the method described herein. Hole-transporting materials useful in hole-transporting layer 440 are well known to include compounds such as an aromatic tertiary amine, where the latter is understood to be a compound containing at least one tuivalent nitrogen atom that is bonded only to carbon atoms, at least one of which is a member of an aromatic ring. In one form the aromatic tertiary amine can be an arylamine such as a monoarylamine, diarylamine, triarylamine, or a polymeric arylamine. U.S. Pat. No. 3,180,730 illustrates exemplary monomeric triarylamines. Other suitable triarylamines substituted with one or in U.S. Pat. Nos. 3,567,450 and 3,658,520, Brantley et al. disclose more vinyl radicals and comprises at least one active hydrogen-containing group.

In U.S. Pat. Nos. 4,720,432 and 5,061,569, a more preferred class of aromatic tertiary amines are those which include at least two aromatic tertiary amine moieties as described. Such compounds include those represented by structural Formula A.

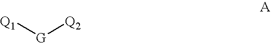

wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q1 or Q2 contains a polycyclic fused ring structure, for example, a naphthalene. When G is an aryl group, it is conveniently a phenylene, biphenylene, or naphthalene moiety.

A useful class of triarylamines satisfying structural Formula A and containing two triarylamine moieties is represented by structural Formula B.

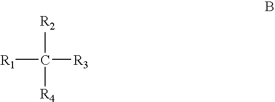

where:

R₁ and R₂ each independently represent a hydrogen atom, an aryl group, or an alkyl group or R₁ and R₂ together represent the atoms completing a cycloalkyl group; and

R₃ and R₄ each independently represent an aryl group, which is in turn substituted with a diaryl substituted amino group, as indicated by structural Formula C.

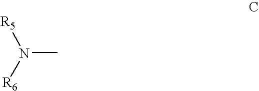

wherein R₅ and R₆ are independently selected aryl groups. In one embodiment, at least one of R₅ or R₆ contains a polycyclic fused ring structure, for example, a naphthalene.

Another class of aromatic tertiary amines are the tetraaiyldiamines. Desirable tetraaryldiamines include two diarylamino groups, such as indicated by Formula C, and linked through an arylene group. Useful tetraaryldiamines include those represented by Formula D.

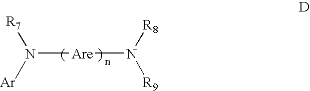

wherein:

each Are is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, for example, a naphthalene.

The various alkyl, alkylene, aryl. and arylene moieties of the foregoing structural Formulae A, B, C, D, can each in turn be substituted. Typical substituents include alkyl groups. alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms—for example, cyclopentyl, cyclohexyl, and cycloheptyl ring structures. The aryl and arylene moieties are usually phenyl and phenylene moieties.

The hole-transporting layer in an OLED device can be formned of a single or a mixture of aromatic tertiary amine compounds. Specifically, one can employ a triarylamine, such as a triarvlamine satisfying the Formula B, in combination with a tetraaryldiamine, such as indicated by Formula D. When a triarylamine is employed in combination with a tetraaryidiamine, the latter is positioned as a layer interposed between the triaiylamine and the electron-injecting and transporting layer. The device and method described herein can be used to deposit single- or multi-component layers, and can be used to sequentially deposit multiple layers.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-emitting layer 450 produces light in response to hole-electron recombination. Light-emitting layer 450 is commonly disposed over hole-transporting layer 440. Desired organic light-emitting materials can be deposited by any suitable means such as evaporation, sputtering, chemical vapor deposition, electrochemical means, or radiation thermal transfer from a donor material, and can be deposited by the method described herein. Useful organic light-emitting materials are well known. As more fully described in U.S. Pat. Nos. 4,769,292 and 5,935,721, the light-emitting layers of the organic EL element comprise a luminescent or fluorescent material where electroluminescence is produced as a result of electron-hole pair recombination in this region. The light-emitting layers can be comprised of a single material, but more commonly include a host material doped with a guest compound or dopant where light emission comes primarily from the dopant. The dopant is selected to produce color light having a particular spectrum. The host materials in the light-emitting layers can be an electron-transporting material, as defined below, a hole-transporting material, as defined above. or another material that supports hole-electron recombination. The dopant is usually chosen from highly fluorescent dyes. but phosphorescent compounds; for example, transition metal complexes as described in WO 98/55561, WO 00/18851, WO 00/57676, and WO 00/70655 are also usefil. Dopants are typically coated as 0.01 to 10% by weight into the host material. Further, a second host material, or co-host, can be used. The method described herein can be used to coat multi-component guest/host layers without the need for multiple vaporization sources.

Host and emitting molecules known to be of use include, but are not limited to, those disclosed in U.S. Pat. Nos. 4,768,292: 5,141,671; 5,150,006; 5,151,629; 5,294,870; 5,405,709: 5,484,922; 5,593,788; 5,645,948; 5,683,823; 5,755,999; 5,928,802; 5,935,720: 5,935,721; and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, for example, green, yellow, orange, and red.

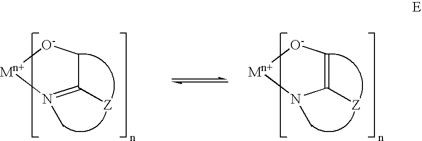

wherein:

M represents a metal;

n is an integer of from 1 to 3; and

Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

The host material in light-emitting layer 450 can be an anthracene derivative having hydrocarbon or substituted hydrocarbon substituents at the 9 and 10 positions. For example, derivatives of 9,10-di-(2-naphthyl)anthracene constitute one class of useful host materials capable of supporting electroluminescence, and are particularly suitable for light emission of wavelengths longer than 400 nm, for example, blue, green, yellow, orange or red.

Benzazole derivatives constitute another class of useful host materials capable of supporting electroluminescence, and are particularly suitable for light emission of wavelengths longer than 400 nm, for example, blue, green, yellow, orange or red. An example of a useful benzazole is 2,2′,2″-(1,3,5-phenylene)tris[1-phenyl-1-H-benzimidazole].

Desirable fluorescent dopants include peiylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds.

Other organic emissive materials can be polymeric substances, for example, polyphenylenevinylene derivatives, dialkoxy-polyphenylenevinylenes, poly-para-phenylene derivatives, and polytluorene derivatives, as taught by Wolk et al. in commonly assigned U.S. Pat. No. 6,194,119 B1 and references cited therein.

While not always necessary, it is often useful that OLED device 410 includes an electron-transporting layer 455 disposed over light-emitting layer 450. Desired electron-transporting materials can be deposited by any suitable means such as evaporation, sputtering, chemical vapor deposition, electrochemical means, thermal transfer, or laser thermal transfer from a donor material, and can be deposited by the method described herein. Preferred electron-transporting materials for use in electron-transporting layer 455 are metal chelated oxinoid compounds, including chelates of oxine itself (also commonly referred to as 8-quinoliniol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials.

Other electron-transporting materials can be polymeric substances, for example, polyphenylenevinylene derivatives, poly-para-phenylene derivatives, polyfluorene derivatives, polythiophenes, polyacetylenes, and other conductive polymeric organic materials such as those listed in Handbook of Conductive Molecules and Polymers, Vols. 1-4, H. S. Nalwa, ed., John Wiley and Sons, Chichester (1997).

An electron-injecting layer 460 can also be present between the cathode and the electron-transporting layer. Examples of electron-injecting materials include alkaline or alkaline earth metals, alkali halide salts, such as LiF mentioned above, or alkaline or alkaline earth metal doped organic layers.

Cathode 490 is formed over the electron-transporting layer 455 or over light-emitting layer 450 if an electron-transporting layer is not used. When light emission is through the anode 430, the cathode material can be comprised of nearly any conductive material. Desirable materials have good film-forming properties to ensure good contact with the underlying organic layer, promote electron injection at low voltage, and have good stability. Useful cathode materials often contain a low work function metal (<3.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of Al as described in U.S. Pat. No. 5,677,572. Other useful cathode materials include, but are not limited to, those disclosed in U.S. Pat. Nos. 5,059,861; 5,059,862; and 6,140,763.

When light emission is viewed through cathode 490, it must be transparent or nearly transparent. For such applications, metals must be thin or one must use transparent conductive oxides, or a combination of these materials. Optically transparent cathodes have been described in more detail in U.S. Pat. No .5,776,623. Evaporation, sputtering, or chemical vapor deposition can deposit cathode materials. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

The invention has been described in detail with particular reference to certain preferred embodiments thereof, but it will be understood that variations and modifications can be effected within the spirit and scope of the invention.

### PARTS LIST

10 vaporization apparatus
20 manifold
25 manifold
30 opening
35 motor
40 first transport apparatus
45 second transport apparatus
50 first container
55 second container
60 transport path
65 transport path
70 third container
75 fourth container
80 auger
90 motor
100 vaporization apparatus
105 vaporization apparatus
110 manifold
115 vaporization apparatus
120 first organic component
125 mixture of organic components
135 crucible
140 heating element
150 opening
160 first organic material
170 heating element
180 base
210 step
215 step
220 substrate
221 step
225 step
230 step
235 step
240 step
245 step
250 step
260 step
265 step
310 desired composition space
320 first mixture
330 second mixture
340 third mixture
350 composition gamut
360 third mixture
370 composition gamut
410 OLED device
420 substrate
430 anode
435 hole-injecting layer
440 hole-transporting layer
450 light-emitting layer
455 electron-transporting layer
460 electron-injecting layer
470 organic layers
490 cathode

1. A method for vaporizing organic components and delivering the vapor through opening(s) in a manifold to a substrate surface spaced from the manifold to form a film composed of at least two organic components, comprising:
a. delivering a first quantity of a single first organic component into a vaporization device where the component is vaporized and delivered at a first predetermined rate to the manifold;
b. delivering into a transport apparatus a quantity of a mixture of organic components in a predetermined ratio that includes the first organic component;
c. the transport apparatus delivering the mixture of organic components at a second predetermined rate to a flash heating region wherein the mixture is vaporized and delivered to the manifold; and
d. mixing the mixed organic components in the manifold, which permits the mixed vaporized components to be deposited through the opening(s) onto the substrate surface to formn the film.

2. The method according to claim 1 further including changing the predetermined rate(s) of the first organic component or the mixture of organic components or both delivered to the manifold to change the composition of the film.

3. The method according to claim 1 further including limiting the ratio of the higher to the lower of the first and second predetermined rates to less than 20:1.

4. The method of claim 1 wherein the mixture of organic components includes a host and a dopant.

5. The method of claim 1 wherein the transport apparatus includes an auger.

6. The method of claim 5 wherein the auger continuously meters the mixture to the flash heating region when vaporization of the mixture is desired and is off only when vaporization of the mixture is not desired.

7. The method of claim 1 wherein at least a portion of the transport apparatus is cooled.

8. The method of claim 1 further comprising providing more than one transport apparatus for delivering more than one mixture of organic components at predetermined rates to corresponding flash heating regions.

9. The method according to claim 8 further including limiting the ratio of the highest to the lowest of the predetermined rates to less than 20:1.

10. The method of claim 8 wherein a first mixture includes a host and dopant and a second mixture includes a host and co-host.

11. The method of claim 8 wherein a first mixture is a mixture of a host and co-host and a second mixture is a mixture of a host, co-host, and dopant.

12. The method of claim 8 wherein the total number of transport apparatus and vaporization devices is equal to or greater than the total number of components in the film.

13. The method of claim 1 further comprising providing at least two vaporization devices wherein at least two single organic components are vaporized and delivered at predetermined rates to the manifold.

14. The method according to claim 13 further including limiting the ratio of the highest to the lowest of the predetennined rates to less than 20:1.

15. The method of claim 13 wherein the total number of transport apparatus and vaporization devices is equal to or greater than the total number of components in the film.

16. A method for vaporizing a mixture of organic components and delivering the vapor through opening(s) in a manifold to a substrate surface spaced from the manifold to form a film, comprising:
a. delivering into a first transport apparatus a first quantity of a first mixture of the organic components having a first predetermined ratio;
b. delivering into a second transport apparatus a second quantity of a second mixture of the organic components that includes at least one organic component of the first mixture and has a second predetermined ratio that is different than the first predetermined ratio;
c. the first and second transport apparatus delivering their corresponding mixtures in predetermined rates to corresponding first and second flash heating regions where the mixtures are vaporized and delivered to the manifold; and
d. mixing the first and second mixtures in the manifold, which permits the mixed vaporized components to be deposited through the opening(s) onto the substrate surface to form the film.

17. The method according to claim 16 further including changing the predetermined rate(s) of the first or second mixture or both delivered by the first or second transport apparatus or both to their corresponding flash heating regions to change the composition of the film.

18. The method according to claim 16 further including limiting the ratio of the higher predetermined rate to the lower predetermined rate to less than 20:1.

19. The method of claim 16 wherein the first and second mixtures are mixtures of a host and a dopant.

20. The method of claim 16 wherein the first and second transport apparatus include augers.

21. The method of claim 20 wherein the first and second augers continuously meter the mixtures to their corresponding first and second flash heating regions when vaporization of the mixtures is desired and are off only when vaporization of the mixtures is not desired.

22. The method of claim 16 wherein at least a portion of first and second transport apparatus are cooled.

23. The method of claim 16 further comprising providing more than two transport apparatus for delivering more than two mixtures of organic components in predeternmined rates to corresponding flash heating regions.

24. The method according to claim 23 further including limiting the ratio of the highest to the lowest of the predetenrnined rates to less than 20:1.

25. The method of claim 23 wherein the first mixture is a mixture of a host and co-host and the second mixture is a mixture of a host and co-host.

26. The method of claim 23 wherein the first mixture is a mixture of a host and co-host and the second mixture is a mixture of a host, co-host, and dopant.

27. The method of claim 23 wherein the total number of transport apparatus is equal to or greater than the total number of components in the film.

28. A method for vaporizing organic components and delivering the vapor through opening(s) in manifolds to a substrate surface spaced from the manifolds to form a film composed of at least two organic components, comprising:
a. delivering a first quantity of a single first organic component into a vaporization device where the component is vaporized and delivered at a first predetermined rate through opening(s) in a first manifold to the space between the first manifold and the substrate;
b. delivering into a transport apparatus a quantity of a mixture of organic components in a predetermined ratio that includes the first organic component;
c. the transport apparatus delivering the mixture of organic components at a second predetermined rate to a flash heating region wherein the mixture is vaporized and delivered through opening(s) in a second manifold to the space between the second manifold and the substrate, and
d. mixing the organic components in the space between the first and second manifolds and the substrate, which permits the mixed vaporized components to be deposited onto the substrate surface to form the film.

29. A method for vaporizing a mixture of organic components and delivering the vapor through opening(s) in manifolds to a substrate surface spaced from the manifold to form a film, comprising:
a. delivering into a first transport apparatus a first quantity of a first mixture of the organic components having a first predetermined ratio;
b. delivering into a second transport apparatus a second quantity of a second mixture of the organic components that includes at least one organic component of the first mixture and has a second predetermined ratio that is different than the first predetermined ratio;
c. the first and second transport apparatus delivering their corresponding mixtures in predetermined rates to corresponding first and second flash heating regions where the mixtures are vaporized and delivered through opening(s) in corresponding first and second manifolds to the space between the first and second manifolds and the substrate; and
d. mixing the organic components in the space between the first and second manifolds and the substrate, which permits the mixed vaporized components to be deposited onto the substrate surface to form the film.
